(19) United States
(12) Patent Application Publication
(10) Pub. No.: US 2008/0124569 A1
(43) Pub. Date: May 29, 2008

(54) Electroluminescent Complexes

(75) Inventors: Poopathy Kathirgamanathan, North Harrow (GB); Sivagnanasundram Surendrakumar, Edgeware (GB)

Correspondence Address: David Silverstein;Andover-IP-Law, 44 Park Street, Suite 300, Andover, MA, 01810, US

(73) Assignee: OLED-T LIMITED, Innova Park, Enfield (GB)

(21) Appl. No.: 11/667,085

(22) PCT Filed: Nov. 4, 2005
(86) PCT No.: PCT/GB2005/004297

§ 371 Date: Jun. 25, 2007

(30) Foreign Application Priority Data
Nov. 5, 2004 (GB) 0424468.7

(51) Int. Cl. C09K 11/06; H01L 51/30

(52) U.S. Cl. 428/690; 568/6; 428/411.1

(57) ABSTRACT

An electroluminescent material is a complex of boron and a beta diketone.

The present invention relates to electroluminescent materials and to electroluminescent devices.

Materials which emit light when an electric current is passed through them are well known and used in a wide range of display applications. Liquid crystal devices and devices which are based on inorganic semiconductor systems are widely used, however these suffer from the disadvantages of high energy consumption, high cost of manufacture, low quantum efficiency and the inability to make flat panel displays.

Organic polymers have been proposed as useful in electroluminescent devices, but it, is not possible to obtain pure colours, they are expensive to make and have a relatively low efficiency.

Another compound which has been proposed is aluminium quinolate, but this requires dopants to be used to obtain a range of colours and has a relatively low efficiency.

Patent application WO98/58037 describes a range of lanthanide complexes which can be used in electroluminescent devices which have improved properties and give better results. Patent Applications PCT/GB98/01773, PCT/GB99/03619, PCT/GB99/04030, PCT/GB99/04024, PCT/GB99/04028, PCT/GB00/00268 describe electroluminescent complexes, structures and devices using rare earth chelates.

U.S. Pat. No. 5,128,587 discloses an electroluminescent device which consists of an organometallic complex of rare earth elements of the lanthanide series sandwiched between a transparent electrode of high work function and a second electrode of low work function with a hole conducting layer interposed between the electroluminescent layer and the transparent high work function electrode and an electron conducting layer interposed between the electroluminescent layer and the electron injecting low work function anode. The hole conducting layer and the electron conducting layer are required to improve the working and the efficiency of the device. The hole transporting layer serves to transport holes and to block the electrons, thus preventing electrons from moving into the electrode without recombining with holes. The recombination of carriers therefore mainly takes place in the emitter layer.

U.S. Pat. Nos. 6,287,713 and 6,368,731 the contents of which are incorporated by reference, disclose electroluminescent compounds which are complexes of boron with 8-aminoquinolate derivatives.

We have now invented electroluminescent compounds which are boron complexes of beta diketones.

According to the invention there is provided an electroluminescent material which is a complex of boron and a beta diketone.

The invention also provides an electroluminescent device which comprises a first electrode, a layer of an electroluminescent material and a second electrode in which the electroluminescent material is a complex of a boron and a beta diketone.

The boron complexes of the present invention are of formula

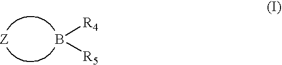

where Z is a beta diketone and R₄ and R₅ which may be the same or different and are substituted and unsubstituted aromatic, heterocyclic or polycyclic groups or fluorocarbons such as trifluoryl methyl groups, halogens such as fluorine or thiophenyl groups.

Examples of Z include

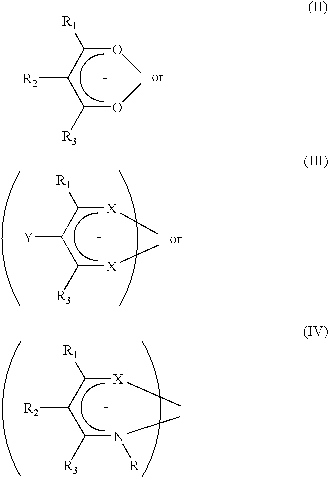

where R₁, R₂ and R₃ can be the same or different and are selected from hydrogen, and substituted and unsubstituted hydrocarbyl groups such as substituted and unsubstituted aliphatic groups, substituted and unsubstituted aromatic, heterocyclic and polycyclic ring structures, fluorocarbons such as trifluoryl methyl groups, halogens such as fluorine or thiophenyl groups; R₁, R₂ and R₃ can also form substituted and unsubstituted fused aromatic, heterocyclic and polycyclic ring structures and can be copolymerisable with a monomer e.g. styrene. X is Se, S or O, Y can be hydrogen, substituted or unsubstituted hydrocarbyl groups, such as substituted and unsubstituted aromatic, heterocyclic and polycyclic ring structures, fluorine, fluorocarbons such as trifluoryl methyl groups, halogens such as fluorine or thiophenyl groups or nitrile.

Examples of R₁ and/or R₂ and/or R₃ include aliphatic, aromatic and heterocyclic alkoxy, aryloxy and carboxy groups, substituted and substituted phenyl, fluorophenyl, biphenyl, phenanthrene, anthracene, naphthyl and fluorene groups C₁-C₄ alkyl groups such as t-butyl, heterocyclic groups such as carbazole and groups and thienyl groups.

Other groups Z include

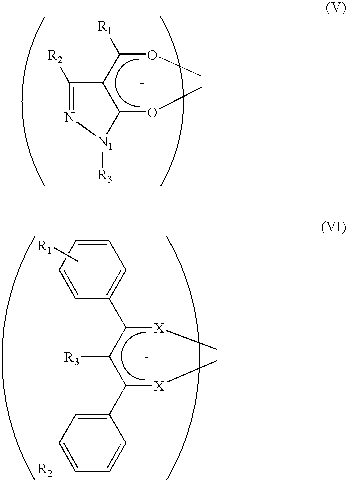

where X is O, S, or Se and R₁, R₂ and R₃ are as above or of formula

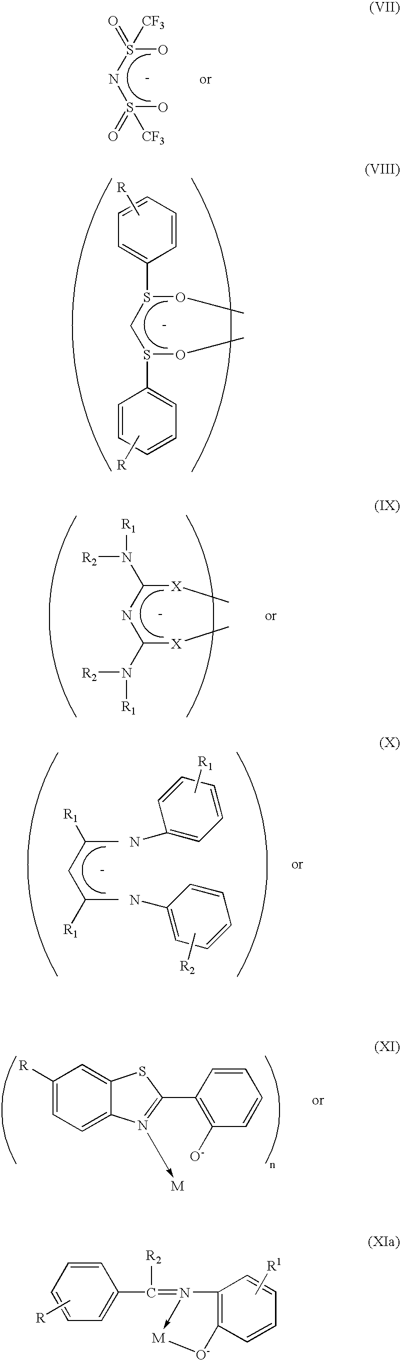

### Where R, R₁ and R₂ are as above.

The boron chelates of the invention can be made by the reaction

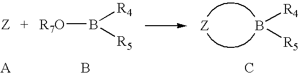

where Z, R₄ and R₅ are as above and R₇ is a functional group so that compound C is a salt or an ester of borinic acid e.g. an amine ester, such as ethanolamine, an amide or an anhydride of borinic acid, which can react with the beta diketone B to form the bis propanedianato-diphenyl compound C. The reaction can take place in an inert solvent such as toluene etc.

The first electrode can function as the anode and the second electrode can function as the cathode and preferably there is a layer of a hole transporting material between the anode and the layer of the electroluminescent compound.

The hole transporting material can be any of the hole transporting materials used in electroluminescent devices.

The hole transporting material can be an amine complex such as α-NBP, poly (vinylcarbazole), N,N′-diphenyl-N,N′-bis(3-methylphenyl)-1,1′-biphenyl-4,4′-diamine (TPD), an unsubstituted or substituted polymer of an amino substituted aromatic compound, a polyaniline, substituted polyanilines, polythiophenes, substituted polythiophenes, polysilanes and substituted polysilanes etc. Examples of polyanilines are polymers of:

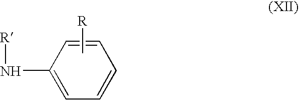

where R is in the ortho- or meta-position and is hydrogen, C1-18 alkyl, C1-6 alkoxy, amino, chloro, bromo, hydroxy or the group:

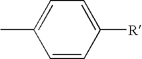

where R is alkyl or aryl and R′ is hydrogen, C1-6 alkyl or aryl with at least one other monomer of formula II above.

Alternatively the hole transporting material can be a polyaniline. Polyanilines which can be used in the present invention have the general formula:

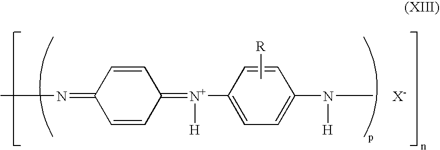

where p is from 1 to 10 and n is from 1 to 20, R is as defined above and X is an anion, preferably selected from Cl, Br, SO₄, BF₄, PF₆, H₂PO₃, H₂PO₄, arylsulphonate, arenedicarboxylate, polystyrenesulphonate, polyacrylate alkylsulphonate, vinylsulphonate, vinylbenzene sulphonate, cellulose sulphonate, camphor sulphonate, cellulose sulphate or a perfluorinated polyanion.

Examples of arylsulphonates are p-toluenesulphonate, benzenesulphonate, 9,10-anthraquinone-sulphonate and anthracenesulphonate. An example of an arenedicarboxylate is phthalate and an example of arenecarboxylate is benzoate.

We have found that protonated polymers of the unsubstituted or substituted polymer of an amino substituted aromatic compound such as a polyaniline are difficult to evaporate or cannot be evaporated. However we have surprisingly found that if the unsubstituted or substituted polymer of an amino substituted aromatic compound is deprotonated, then it can be easily evaporated, i.e. the polymer is evaporable.

Preferably evaporable deprotonated polymers of unsubstituted or substituted polymers of an amino substituted aromatic compound are used. The deprotonated unsubstituted or substituted polymer of an amino substituted aromatic compound can be formed by deprotonating the polymer by treatment with an alkali such as ammonium hydroxide or an alkali metal hydroxide such as sodium hydroxide or potassium hydroxide.

The degree of protonation can be controlled by forming a protonated polyaniline and deprotonating. Methods of preparing polyanilines are described in the article by A. G. MacDiarmid and A. F. Epstein, Faraday Discussions, Chem Soc. 88 P319, 1989.

The conductivity of the polyaniline is dependent on the degree of protonation with the maximum conductivity being when the degree of protonation is between 40 and 60%, for example about 50%.

Preferably the polymer is substantially fully deprotonated.

A polyaniline can be formed of octamer units. i.e. p is four, e.g.

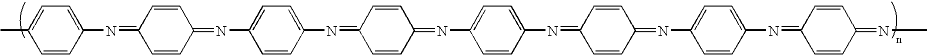

The polyanilines can have conductivities of the order of 1×10⁻¹ Siemen cm⁻¹ or higher.

The aromatic rings can be unsubstituted or substituted, e.g. by a C1 to 20 alkyl group such as ethyl.

The polyaniline can be a copolymer of aniline and preferred copolymers are the copolymers of aniline with o-anisidine, m-sulphanilic acid or o-aminophenol, or o-toluidine with o-aminophenol, o-ethylaniline, o-phenylene diamine or with amino anthracenes.

Other polymers of an amino substituted aromatic compound which can be used include substituted or unsubstituted polyaminonapthalenes, polyaminoanthracenes, polyaminophenanthrenes, etc. and polymers of any other condensed polyaromatic compound. Polyaminoanthracenes and methods of making them are disclosed in U.S. Pat. No. 6,153,726. The aromatic rings can be unsubstituted or substituted, e.g. by a group R as defined above.

Other hole transporting materials are conjugated polymers and the conjugated polymers which can be used can be any of the conjugated polymers disclosed or referred to in U.S. Pat. No. 5,807,627, WO90/13148 and WO92/03490.

The preferred conjugated polymers are poly (p-phenylenevinylene) (PPV) and copolymers including PPV. Other preferred polymers are poly(2,5 dialkoxyphenylene vinylene) such as poly[2-methoxy-5-(2-methoxypentyloxy-1,4-phenylene vinylene)], poly[(2-methoxypentyloxy)-1,4-phenylenevinylene], poly[(2-methoxy-5-(2-dodecyloxy-1,4-phenylenevinylene)] and other poly(2,5 dialkoxyphenylenevinylenes) with at least one of the alkoxy groups being a long chain solubilising alkoxy group, polyfluorenes and oligofluorenes, polyphenylenes and oligophenylenes, polyanthracenes and oligoanthracenes, polythiophenes and oligothiophenes.

In PPV the phenylene ring may optionally carry one or more substituents, e.g. each independently selected from alkyl, preferably methyl, or alkoxy, preferably methoxy or ethoxy.

In polyfluorene, the fluorene ring may optionally carry one or more substituents e.g. each independently selected from alkyl, preferably methyl, or alkoxy, preferably methoxy or ethoxy.

Any poly(arylenevinylene) including substituted derivatives thereof can be used and the phenylene ring in poly(p-phenylenevinylene) may be replaced by a fused ring system such as an anthracene or naphthalene ring and the number of vinylene groups in each poly(phenylenevinylene) moiety can be increased, e.g. up to 7 or higher.

The conjugated polymers can be made by the methods disclosed in U.S. Pat. No. 5,807,627, WO90/13148 and WO92/03490.

The thickness of the hole transporting layer is preferably 20 nm to 200 nm.

The polymers of an amino substituted aromatic compound such as polyanilines referred to above can also be used as buffer layers with or in conjunction with other hole transporting materials e.g. between the anode and the hole transporting layer. Other buffer layers can be formed of phthalocyanines such as copper phthalocyanine and metal aryl-porphonato complex such as tetra-p-tolylporphine)zinc(II).

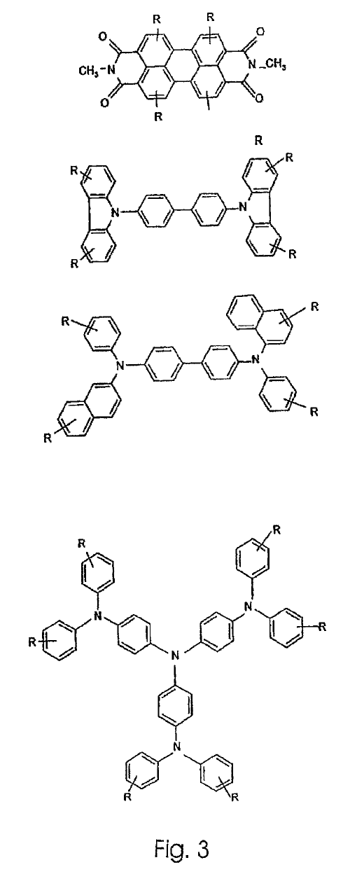

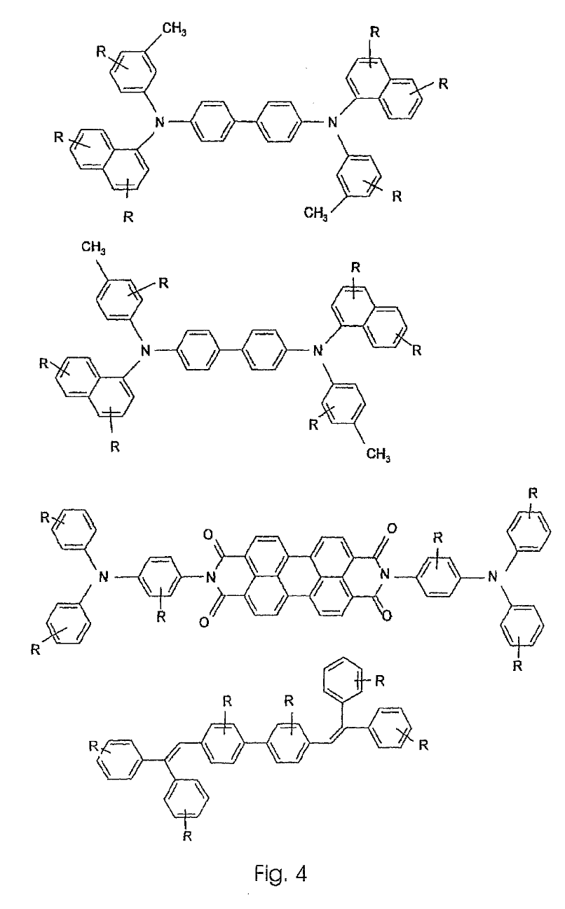

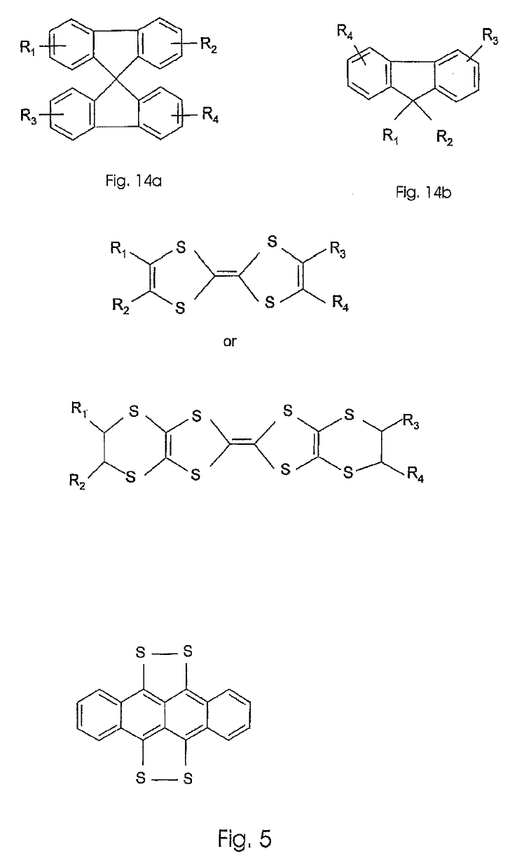

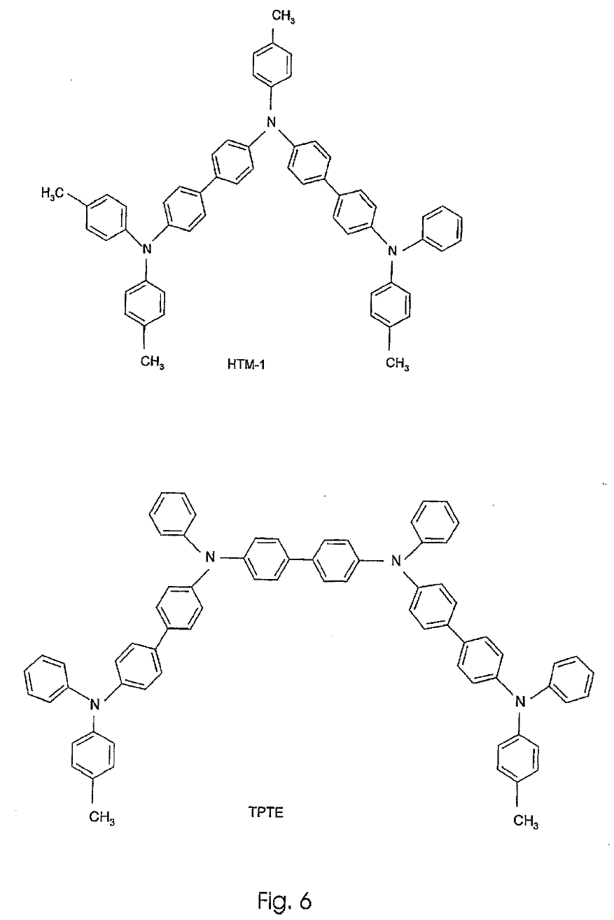

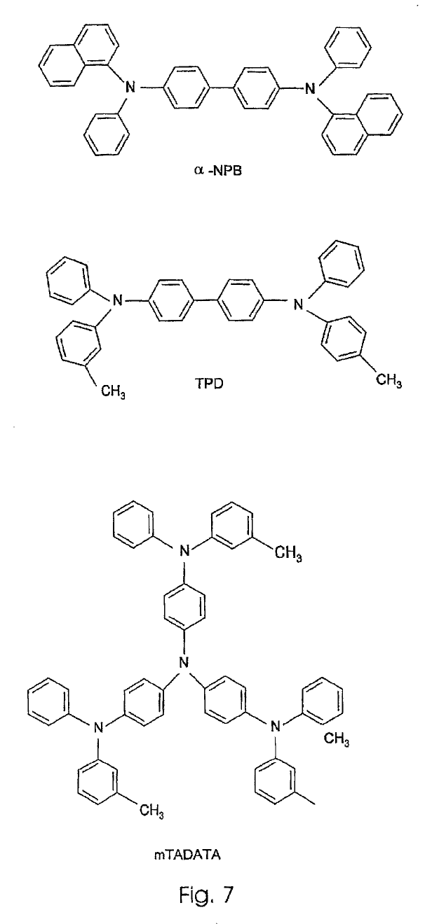

The structural formulae of some other hole transporting materials are shown in FIGS. 3, 4, 5, 6 and 7 of the drawings, where R, R¹, R², R³ and R⁴ can be the same or different and are selected from hydrogen, substituted and unsubstituted hydrocarbyl groups such as substituted and unsubstituted aliphatic groups, substituted and unsubstituted aromatic, heterocyclic and polycyclic ring structures, fluorocarbon groups such as trifluoromethyl, halogens such as fluorine or thiophenyl groups; R, R¹, R², R³ and R⁴ can also form substituted and unsubstituted fused aromatic, heterocyclic and polycyclic ring structures and can be copolymerisable with a monomer, e.g. styrene. X is Se, S or O, Y can be hydrogen, substituted or unsubstituted hydrocarboxyl groups, such as substituted and unsubstituted aromatic, heterocyclic and polycyclic ring structures, fluorocarbon groups such as trifluoromethyl, halogens such as fluorine, thiophenyl or nitrile groups .

Examples of R and/or R¹ and/or R² and/or R³ and/or R⁴ include aliphatic, aromatic and heterocyclic groups, alkoxy, aryloxy and carboxy groups, substituted and unsubstituted phenyl, fluorophenyl, biphenyl, naphthyl, fluorenyl, anthracenyl and phenanthrenyl groups, alkyl groups such as t-butyl, and heterocyclic groups such as carbazole.

Another hole transporting material is an inorganic charge transporting material such as a p-type semiconductor e.g. p-ZnS, p-ZnO, p-CdTe, p-IiP, p-GaAs and p-Si.

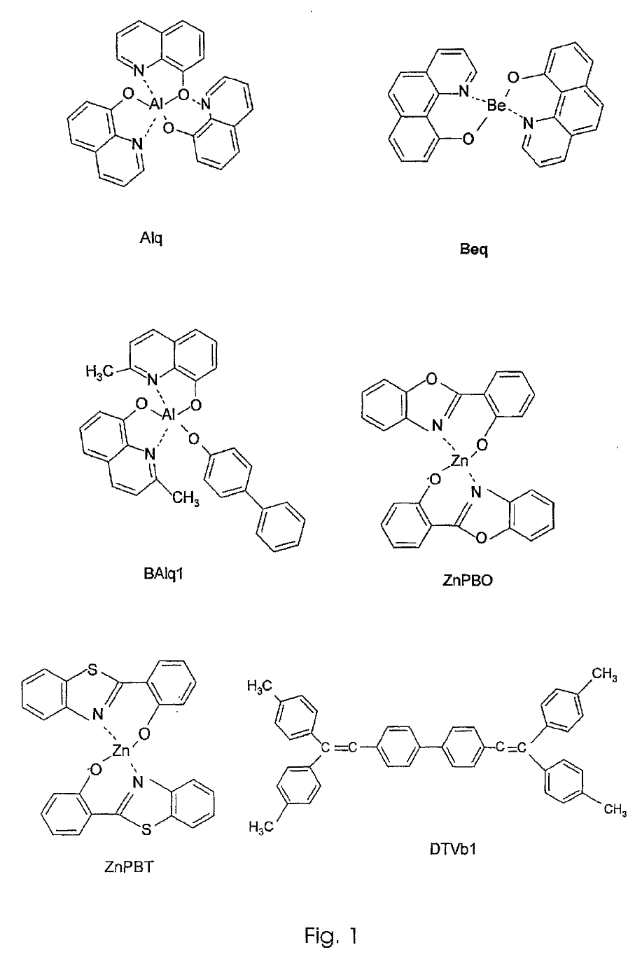

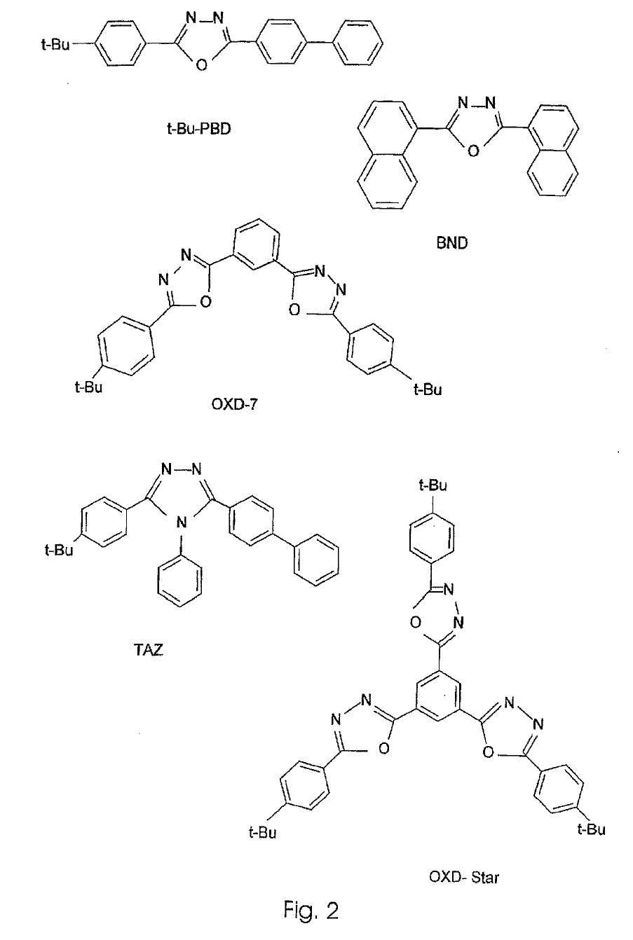

Optionally there is a layer of an electron injecting material between the anode and the electroluminescent material layer. The electron injecting material is a material which will transport electrons when an electric current is passed through. Electron injecting materials include a metal complex such as a metal quinolate, e.g. an aluminium quinolate, lithium quinolate, zirconium quinolate (Zrq₄), a cyanoanthracene such as 9,10-dicyanoanthracene, cyano substituted aromatic compounds, tetracyanoquinodimethane, a polystyrene sulphonate or a compound with the structural formulae shown in FIG. 1 or 2 of the drawings or Mx(DBM)ₙ where Mx is a metal and DBM is dibenzoyl methane and n is the valency of Mx e.g. Mx is aluminium or chromium. A Schiff base can also be used in place of the DBM moiety.

Instead of being a separate layer the electron injecting material can be mixed with the electroluminescent material and co-deposited with it.

Other electron injecting materials are inorganic charge transporting materials such as n-type semiconductors e.g. n-CdSe, N-ZnSe, n-CdTe, n-ITO (indium tin oxide), n-GaAs and n-Si.

Optionally the hole transporting material can be mixed with the electroluminescent material and co-deposited with it and the electron injecting materials and the electroluminescent materials can be mixed. The hole transporting materials, the electroluminescent materials and the electron injecting materials can be mixed together to form one layer, which simplifies the construction.

The first electrode is preferably a transparent substrate such as a conductive glass or plastic material which acts as the anode; preferred substrates are conductive glasses such as indium tin oxide coated glass, but any glass which is conductive or has a conductive layer such as a metal or conductive polymer can be used. Conductive polymers and conductive polymer coated glass or plastics materials can also be used as the substrate.

The cathode is preferably a low work function metal, e.g. aluminium, barium, calcium, lithium, rare earth metals, transition metals, magnesium and alloys thereof such as silver/magnesium alloys, rare earth metal alloys etc; aluminium is a preferred metal. A metal fluoride such as an alkali metal e.g. lithium fluoride or rare earth metal or their alloys can be used as the second electrode, for example by having a metal fluoride layer formed on a metal.

The iridium or other metal complex can be mixed with a host material.

The devices of the present invention can be used as displays in video displays, mobile telephones, portable computers and any other application where an electronically controlled visual image is used. The devices of the present invention can be used in both active and passive applications of such displays.

In known electroluminescent devices either one or both electrodes can be formed of silicon and the electroluminescent material and intervening layers of hole transporting and electron transporting materials can be formed as pixels on the silicon substrate. Preferably each pixel comprises at least one layer of an electroluminescent material and a (at least semi-) transparent electrode in contact with the organic layer on a side thereof remote from the substrate.

Preferably, the substrate is of crystalline silicon and the surface of the substrate may be polished or smoothed to produce a flat surface prior to the deposition of electrode, or electroluminescent compound. Alternatively a non-planarised silicon substrate can be coated with a layer of conducting polymer to provide a smooth, flat surface prior to deposition of further materials.

In one embodiment, each pixel comprises a metal electrode in contact with the substrate. Depending on the relative work functions of the metal and transparent electrodes, either may serve as the anode with the other constituting the cathode.

When the silicon substrate is the cathode an indium tin oxide coated glass can act as the anode and light is emitted through the anode. When the silicon substrate acts as the anode, the cathode can be formed of a transparent electrode which has a suitable work function; for example by an indium zinc oxide coated glass in which the indium zinc oxide has a low work function. The anode can have a transparent coating of a metal formed on it to give a suitable work function. These devices are sometimes referred to as top emitting devices or back emitting devices.

The metal electrode may consist of a plurality of metal layers; for example a higher work function metal such as aluminium deposited on the substrate and a lower work function metal such as calcium deposited on the higher work function metal. In another example, a further layer of conducting polymer lies on top of a stable metal such as aluminium.

Preferably, the electrode also acts as a mirror behind each pixel and is either deposited on, or sunk into, the planarised surface of the substrate. However, there may alternatively be a light absorbing black layer adjacent to the substrate.

In still another embodiment, selective regions of a bottom conducting polymer layer are made non-conducting by exposure to a suitable aqueous solution allowing formation of arrays of conducting pixel pads which serve as the bottom contacts of the pixel electrodes.

The preparation and properties of born complexes of the invention are set out in the examples.

### EXAMPLE 1

### 1,3-Bis(4-methoxyphenyl)-1,3-propanedionato-diphenyl boron

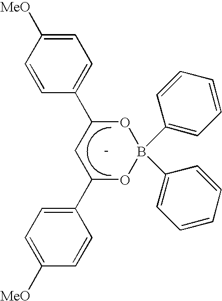

Procedure

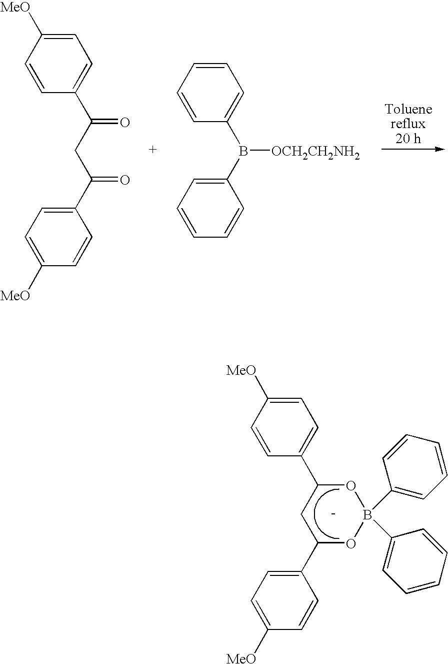

1,3-Bis(4-methoxyphenyl)-1,3-propanedione (0.5 g, 1.76 mmole) and diphenylborinic acid ethanolamine ester (0.42 g, 1.86 mmole) were mixed together and refluxed in toluene (10 ml) for 20 hours. On cooling the reaction mixture, an orange crystalline solid formed. The solid was filtered off under suction, washed with small amounts of toluene and dried in vacuo at 80° C. for 12 hours. M.p 193° C. (DSC).

Elemental analysis

| ELEMENT | C | H |
|---|---|---|
| % Theory | 77.69 | 5.62 |
| % Found | 77.14 | 5.81 |

The complexes were found to be photoluminescent and electroluminescent and the properties were:

PL efficiency: 0.002 cdm⁻² μW⁻¹

Colour according to the CIE colour Chart (1931) (x, y): (0.33, 0.55)

Peak: 525 nm

Photoluminescence was excited using 325 nm line of Liconix 4207 NB, He/Cd laser. The laser power incident at the sample (0.3 mWcm⁻²) was measured by a Liconix 55PM laser power meter. The radiance calibration was carried out using Bentham radiance standard (Bentham SRS8, Lamp current 4,000 A, calibrated by National Physical laboratories, England. The PL studies were carried out on samples or films.

### EXAMPLE 2

### 1,3-Bis(3,4-dimethoxyphenyl)-1,3-propanedionato-diphenyl boron

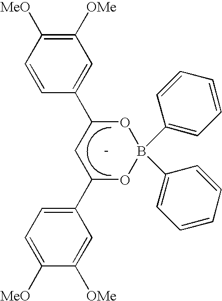

Procedure

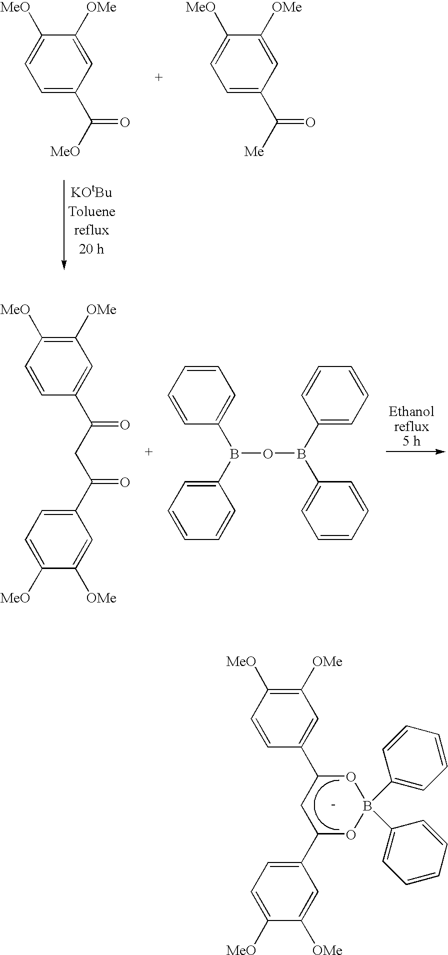

3,4-Dimethoxyacetophenone (10.0 g, 0.056 mole) was dissolved in dry toluene (50 ml) and to the magnetically stirred solution was added potassium tert-butoxide (7.5 g, 0.067 mole) all at once using a powder funnel. Methyl 3,4-dimethoxy benzoate (12.0 g, 0.06 mole) was dissolved in dry toluene (75 ml) and then added slowly to the stirred solution. Further toluene (25 ml) was added to wash the funnel. The reaction mixture became orange in colour and refluxed gently under nitrogen atmosphere for 20 hours. The cooled solution was acidified with 1M hydrochloric acid and extracted in the usual manner. The product was recrystallised from methanol to give an yellow-orange solid, 12.0 g (63%). M.p 137° C. (DSC). The bis (3,4-dimethoxybenzoyl) methane (0.5 g, 1.45 mmole) was taken-up with dry ethanol (magnesium/iodine) (10 ml) and to the magnetically stirred solution diphenylborinic anhydride (0.51 g, 1.47 mmole) in dry ethanol (40 ml) was added under nitrogen atmosphere. The reaction mixture became deep yellow in colour and was refluxed for 3 hours. The solution was cloudy; therefore further dry ethanol (25 ml) was added to the reaction mixture and refluxed for another 2 hours. The solution was filtered, the filtrate concentrated and allowed to cool overnight to give a yellow crystalline solid, 0.68 g (92%). M.p 242° C. (DSC).

Elemental analysis

| ELEMENT | C | H |
|---|---|---|
| % Theory | 73.24 | 5.75 |
| % Found | 73.24 | 5.72 |

The properties were measured as in Example 1 and were:

PL efficiency: 0.035 cdm⁻² μW⁻¹

(x, y): (0.44, 0.53)

Peak: 560 mn

1.-33. (canceled)

34. An electroluminescent material which is a complex of boron and a beta diketone having the general chemical formula 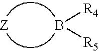
wherein: Z is a beta diketone; and R₄ and R₅, which may be the same or different, are independently selected from the group consisting of substituted and unsubstituted aromatic, heterocyclic or polycyclic groups, fluorocarbons, halogens and thiophenyl groups.

35. The material of claim 34 wherein Z has a general chemical formula selected from the group consisting of: 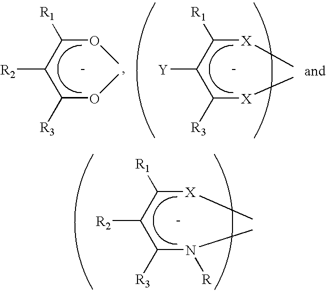
wherein: R₁, R₂ and R₃ can be the same or different and are independently selected from the group consisting of hydrogen, substituted and unsubstituted hydrocarbyl groups, substituted and unsubstituted aliphatic groups, substituted and unsubstituted aromatic, heterocyclic and polycyclic ring structures, fluorocarbons, halogens and thiophenyl groups; X is Se, S or O; and Y is selected from the group consisting of hydrogen, substituted or unsubstituted hydrocarbyl groups, substituted and unsubstituted aromatic, heterocyclic and polycyclic ring structures, fluorocarbons, halogens, thiophenyl groups, and nitrile.

36. The material of claim 35 wherein R₁, R₂ and R₃ form substituted and unsubstituted fused aromatic, heterocyclic or polycyclic ring structures or are copolymerisable with a monomer.

37. The material of claim 35 wherein at least one of R₁, R₂ and R₃ includes a group selected from the group consisting of aliphatic, aromatic, heterocyclic alkoxy, aryloxy, carboxy, substituted and unsubstituted phenyl, fluorophenyl, biphenyl, phenanthrene, anthracene, naphthyl, fluorine, alkyl, heterocyclic, and thienyl groups.

38. The material of claim 34, wherein Z has a general chemical formula selected from the group consisting of 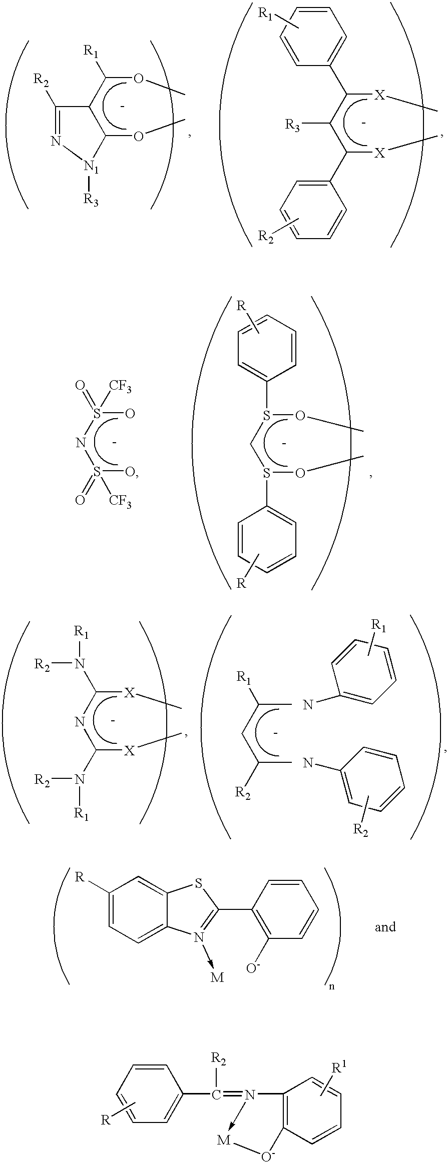
substituted and unsubstituted aromatic, heterocyclic and polycyclic ring structures, fluorocarbons, halogens and thiophenyl groups.
wherein X is Se, S or O; and R₁, R₂ and R₃ can be the same or different and are independently selected from the group consisting of hydrogen, substituted and unsubstituted hydrocarbyl groups, substituted and unsubstituted aliphatic groups, substituted and unsubstituted aromatic, heterocyclic and polycyclic ring structures, fluorocarbons, halogens and thiophenyl groups.

39. An electroluminescent device which comprises a first electrode, a second electrode, and a layer of an electroluminescent material as claimed in claim 34 located between said first and second electrodes.

40. The device of claim 39, wherein a layer of a hole transmitting material is positioned between the first electrode and the layer of an electroluminescent material.

41. The device of claim 40, wherein the hole transmitting material is selected from the group consisting of
(a) a polyaromatic amine;
(b) a polyaninine;
(c) a copolymer of aniline with o-anisidine, m-sulphanilic acid, o-aminophenol, o-toluidine, o-aminophenol, o-ethylaniline, o-phenylene diamine, or with an amino anthracene;
(d) a conjugated polymer selected from poly (p-phenylenevinylene)-PPV and copolymers of PPV, poly(2,5 dialkoxyphenylene vinylene), poly(2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene), other poly(2,5 dialkoxyphenylenevinylenes) wherein at least one of the alkoxy groups is a long chain solubilising alkoxy group, polyfluorenes, oligofluorenes, polyphenylenes, oligophenylenes, polyanthracenes, oligo anthracenes, polythiophenes and oligothiophenes; and
(e) a film of a polymer selected from the group consisting of poly(vinylcarbazole), N,N′-diphenyl-N,N′-bis(3-methylphenyl)-1,1′-biphenyl-4,4′-diamine (TPD), polyaniline, substituted polyanilines, polythiophenes, substituted polythiophenes, polysilanes and substituted polysilanes.

42. The device of claim 40, wherein the hole transmitting material is selected from the group consisting of HTM-1, TPTE, α-NBP, TPD and mTADATA.

43. The device of claim 39 wherein a layer of an electron transmitting material is positioned between an electrode that serves as a cathode and the layer of the electroluminescent material.

44. The device of claim 43 wherein the electron transmitting material is a metal quinolate.

45. The device of claim 44 wherein the metal quinolate is an aluminum quinolate, zirconium quinolate or lithium quinolate.

46. The device of claim 43 wherein the electron transmitting material is selected from the group consisting of:
(a) a material having the general chemical formula Mx(DBM)ₙ, where Mx is a metal, DBM is dibenzoyl methane, and n is the valence of Mx;
(b) a material having the general chemical formula Mx(SB)ₙ, where Mx is a metal, SB is a Schiff base, and n is the valence of Mx;
(c) a cyano anthracene or a polystyrene sulphonate; and,
(d) a material selected from the group consisting of Bew, ZnPBO, ZnPBT, DTVb1, t-Bu-PBD, BND, OXD-7, TAZ and OXD-star.

47. The device of claim 39, wherein the first electrode comprises a transparent conductive glass electrode.

48. The device of claim 39, wherein the second electrode comprises a material selected from the group consisting of aluminum, barium, rare earth metals, transition metals, calcium, lithium, magnesium and alloys thereof, and silver/magnesium alloys.

49. The device of claim 39, wherein the second electrode comprises a metal having a metal fluoride layer of the metal formed thereon.

50. The device of claim 49, wherein the metal fluoride is a lithium fluoride or a rare earth fluoride.
